(19) United States
(12) Patent Application Publication
(10) Pub. No.: US 2010/0246299 A1
(43) Pub. Date: Sep. 30, 2010

(54) SEMICONDUCTOR STORAGE DEVICE AND REDUNDANCY METHOD

(75) Inventors: Takayuki IWAI, Tokyo (JP); Mariko IIZUKA, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/559,925

(22) Filed: Sep. 15, 2009

(30) Foreign Application Priority Data
Mar. 24, 2009 (JP) 2009-071704

(51) Int. Cl. G11C 29/00; G11C 7/00

(52) U.S. Cl. 365/200; 365/222; 365/194

(57) ABSTRACT

A semiconductor storage device includes a normal area that contains a plurality of memory cells and a redundancy area that contains a plurality of memory cells. The semiconductor storage device further includes a delaying unit that changes, between a first mode in which both the normal area and the redundancy area are used and a second mode in which only the normal area is used without use of the redundancy area, a timing for issuing a cell-array control signal for selecting a memory cell from among the memory cells used in a corresponding mode.

### CROSS-REFERENCE TO RELATED APPLICATIONS

This application is based upon and claims the benefit of priority from the prior Japanese Patent Applications No. 2009-071704, filed on Mar. 24, 2009, the entire contents of which are incorporated herein by reference.

### BACKGROUND OF THE INVENTION

1. Field of the Invention

The present invention relates to a semiconductor storage device and a redundancy method implemented by the semiconductor storage device.

2. Description of the Related Art

In recent years, an embedded memory that enables high-speed random access is becoming increasingly important as an alternative to a static random access memory (SRAM) because the embedded memory consumes little power and has a small footprint. A typical embedded memory is provided with row redundancy and column redundancy to improve manufacturing yield thereof.

When the embedded memory is provided with the redundancy, it is necessary to determine whether an address input from an external apparatus corresponds to a repair target. More specifically, when the embedded memory is provided with row redundancy, it is necessary to compare a defective row address information stored in advance in a memory macro with a row address input from the external apparatus by using an address comparator (see, for example, Japanese Patent Application Laid-open No. H10-40694). However, it takes time for the address comparator to compare the defective row address information with the row address information input from the external apparatus, resulting in increased tRC (Row Cycle Time) of the embedded memory. Therefore, performance of the embedded memory degrades.

Furthermore, when the embedded memory is provided with column redundancy, and if a shift redundancy system is employed, it is necessary to guide data to pass through a shift switch. However, it takes time to guide the data to pass through the shift switch, resulting in increased tRC of the embedded memory. Therefore, performance of the embedded memory also degrades.

As an alternative to the above-mentioned technology for providing both the row redundancy and the column redundancy, a technology for providing an error correction code (ECC) in the embedded memory instead of the row redundancy to increase the memory manufacturing yield has been proposed. With use of the ECC, the tRC can be reduced; however, power consumption and a footprint of the embedded memory increase, which is problematic.

### SUMMARY OF THE INVENTION

According to one aspect of the present invention, a semiconductor storage device that includes a normal area having a plurality of memory cells incorporated therein and a redundancy area having a plurality of memory cells incorporated therein, the semiconductor storage device includes a delaying unit that changes, between a first mode in which both the normal area and the redundancy area are used and a second mode in which only the normal area is used without use of the redundancy area, a timing for issuing a cell-array control signal for selecting a memory cell from among the memory cells used in a corresponding mode.

According to another aspect of the present invention, a redundancy method implemented by a semiconductor storage device that includes a normal area having a plurality of memory cells incorporated therein and a redundancy area having a plurality of memory cells incorporated therein, the redundancy method includes changing, between a first mode in which both the normal area and the redundancy area are used and a second mode in which only the normal area is used without use of the redundancy area, a timing for issuing a cell-array control signal for selecting a memory cell from among the memory cells used in a corresponding mode.

### BRIEF DESCRIPTION OF THE DRAWINGS

FIG. 1A is a diagram of a basic configuration of a semiconductor storage device according to an embodiment of the present invention;

FIG. 1B is a diagram of a modified example of the basic configuration of the semiconductor storage device according to the embodiment;

FIG. 2A is a diagram of a detailed configuration of a row path of the semiconductor storage device shown in FIG. 1A;

FIG. 2B is a diagram for explaining operation in the row path of the semiconductor storage device shown in FIG. 2A when a local mode selection signal LMODEn=H (i.e., in a low power consumption mode);

FIG. 2C is a diagram for explaining operation in the row path of the semiconductor storage device shown in FIG. 2A when the local mode selection signal LMODEn=L (i.e., in a high-speed operation mode);

FIG. 2D is a timing diagram for selecting a spare word line in the row path of the semiconductor storage device shown in FIG. 2A in the low power consumption mode;

FIG. 2E is a timing diagram for selecting a normal word line in the row path of the semiconductor storage device shown in FIG. 2A in the low power consumption mode;

FIG. 2F is a timing diagram of operation in the row path of the semiconductor storage device shown in FIG. 2A in the high-speed operation mode;

FIG. 3 is a diagram illustrating detailed configurations of a spare word-line circuit block and a normal word-line circuit block shown in FIG. 2A;

FIG. 4A is a diagram of the semiconductor storage device according to the embodiment including a circuit that performs refresh control;

FIG. 4B is a timing diagram of operation performed by the semiconductor storage device shown in FIG. 4A in the low power consumption mode;

FIG. 4C is a timing diagram of operation performed by the semiconductor storage device shown in FIG. 4A in the high-speed operation mode;

FIG. 5A is a diagram of a detailed configuration of a column path of the semiconductor storage device shown in FIG. 1A;

FIG. 5B is a timing diagram of write operation in the column path of the semiconductor storage device shown in FIG. 5A in the low power consumption mode;

FIG. 5C is a timing diagram of write operation in the column path of the semiconductor storage device shown in FIG. 5A in the high-speed operation mode;

FIG. 5D is a timing diagram of read operation in the column path of the semiconductor storage device shown in FIG. 5A in the low power consumption mode;

FIG. 5E is a timing diagram of read operation in the column path of the semiconductor storage device shown in FIG. 5A in the high-speed operation mode;

FIG. 6A is a diagram illustrating a procedure for switching the low power consumption mode with redundancy to the high-speed operation mode without the redundancy;

FIG. 6B is a diagram illustrating a procedure for switching the high-speed operation mode without the redundancy to the low power consumption mode with the redundancy;

FIG. 7A is a diagram illustrating a procedure for switching the low power consumption mode with row redundancy to the high-speed operation mode without the row redundancy;

FIG. 7B is a diagram illustrating a procedure for switching the high-speed operation mode without the row redundancy to the low power consumption mode with the row redundancy;

FIG. 8A is a diagram illustrating a procedure for switching the low power consumption mode with column redundancy to the high-speed operation mode without the column redundancy;

FIG. 8B is a diagram illustrating a procedure for switching the high-speed operation mode without the column redundancy to the low power consumption mode with the column redundancy;

FIG. 9 is a schematic diagram for explaining how data is copied when the low power consumption mode is switched to the high-speed operation mode; and

FIG. 10 is a schematic diagram for explaining how data is copied when the high-speed operation mode is switched to the low power consumption mode.

### DETAILED DESCRIPTION OF THE PREFERRED EMBODIMENTS

Exemplary embodiments of a semiconductor storage device and a redundancy method implemented by the semiconductor storage device according to the present invention are explained in detail below with reference to the accompanying drawings. The present invention is not limited to the following embodiments.

In the following description, an embedded memory that enables random access is explained as an example of the semiconductor storage device according to the embodiment. The semiconductor storage device according to the embodiment is configured to realize both an improvement of random access speed and reduction of power consumption. For example, in an application such as a cache, the embedded memory is generally not accessed continuously, that is, the embedded memory is accessed frequently in a certain period of time but is infrequently accessed in another period of the time. As one technique to reduce standby power during a time when the embedded memory is infrequently accessed, the number of refreshes during the time is decreased, resulting in large reduction of entire power consumption.

The semiconductor storage device according to the embodiment repairs, when not required to perform high-speed operation (including a period of time when the semiconductor storage device is not accessed; hereinafter, referred to as “a low power consumption mode”), a cell in which retention failure or the like occurs by using redundancy to decrease the number of refreshes to thereby reduce power consumption. On the other hand, when required to perform the high-speed operation (hereinafter, referred to as “a high-speed operation mode”), the semiconductor storage device decreases tRC (Row Cycle Time) without using the redundancy to improve performance thereof.

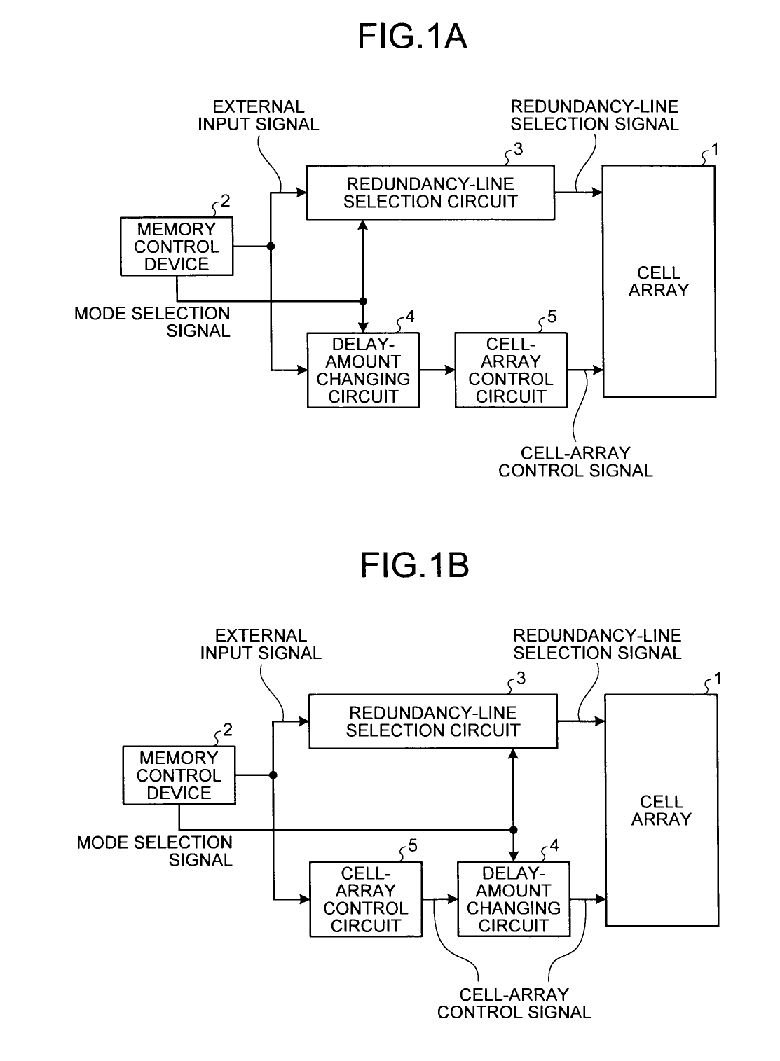

FIG. 1A is a diagram of a basic configuration of the semiconductor storage device according to the embodiment. The semiconductor storage device shown in FIG. 1A has the low power consumption mode with the redundancy and the high-speed operation mode without the redundancy, and includes a cell array 1, a memory control device 2, a redundancy-line selection circuit 3, a delay-amount changing circuit 4, and a cell-array control circuit 5.

The cell array 1 includes a normal area containing a plurality of memory cells, a redundancy area containing a plurality of memory cells, a sense amplifier, a word-line driver, and the like.

The memory control device 2 can be formed of a general memory controller, a CPU, and the like. Any circuits capable of controlling operation of a memory can be employed as the memory control device 2. The memory control device 2 outputs an external input signal to the redundancy-line selection circuit 3 and the delay-amount changing circuit 4. The memory control device 2 also outputs a mode selection signal for selecting either the low power consumption mode (a first mode) or the high-speed operation mode (a second mode) to the redundancy-line selection circuit 3 and the delay-amount changing circuit 4. Based on the mode selection signal, whether to use the redundancy-line selection circuit 3 is determined and the amount of delay set by the delay-amount changing circuit 4 is changed.

The redundancy-line selection circuit 3 outputs, when the mode selection signal indicates selection of the low power consumption mode, a redundancy-line selection signal to the cell array 1 based on the external input signal. On the other hand, when the mode selection signal indicates selection of the high-speed operation mode, the redundancy-line selection circuit 3 does not output the redundancy-line selection signal to the cell array 1. In other words, the redundancy-line selection circuit 3 is used when the mode selection signal indicates the selection of the low power consumption mode, but is not used when the mode selection signal indicates the selection of the high-speed operation mode.

The delay-amount changing circuit 4 is a circuit for setting the amount of delay to be added to an input signal. When the mode selection signal indicates the selection of the low power consumption mode, the delay-amount changing circuit 4 sets the amount of delay to large. On the other hand, when the mode selection signal indicates the selection of the high-speed operation mode, the delay-amount changing circuit 4 sets the amount of delay to small (or “0”). Then, the delay-amount changing circuit 4 outputs the external input signal to the cell-array control circuit 5 after a delay of the set amount of delay. In other words, the delay-amount changing circuit 4 changes a timing of issue of a cell-array control signal between the low power consumption mode and the high-speed operation mode such that a larger amount of delay is set in the low power consumption mode than that in the high-speed operation mode.

The cell-array control circuit 5 generates the cell-array control signal for selecting a memory cell based on the external input signal that has passed through the delay-amount changing circuit 4, and outputs the cell-array control signal to the cell array 1.

FIG. 1B is a diagram of a modified example of the basic configuration of the semiconductor storage device according to the embodiment. While, in the configuration shown in FIG. 1A, the cell-array control circuit 5 is located downstream of the delay-amount changing circuit 4, the delay-amount changing circuit 4 can be located downstream of the cell-array control circuit 5 as shown in FIG. 1B. In FIG. 1B, the cell-array control circuit 5 generates the cell-array control signal based on the external input signal, and outputs the cell-array control signal to the delay-amount changing circuit 4. The delay-amount changing circuit 4 outputs the input cell-array control signal to the cell array 1 after a delay of the set amount of delay.

The semiconductor storage device according to the embodiment has the low power consumption mode with the redundancy and the high-speed operation mode without the redundancy, and includes the delay-amount changing circuit 4 that changes a timing of issue of the cell-array control signal for selecting a memory cell. Therefore, the tRC in the high-speed operation mode can be reduced compared to the tRC in the low power consumption mode.

While, in the embodiment, it is assumed that the two modes are employed such that the delay-amount changing circuit 4 sets the amounts of delay at two different levels, it is possible to employ three or more modes such that the delay-amount changing circuit 4 sets the amounts of delay at three or more different levels.

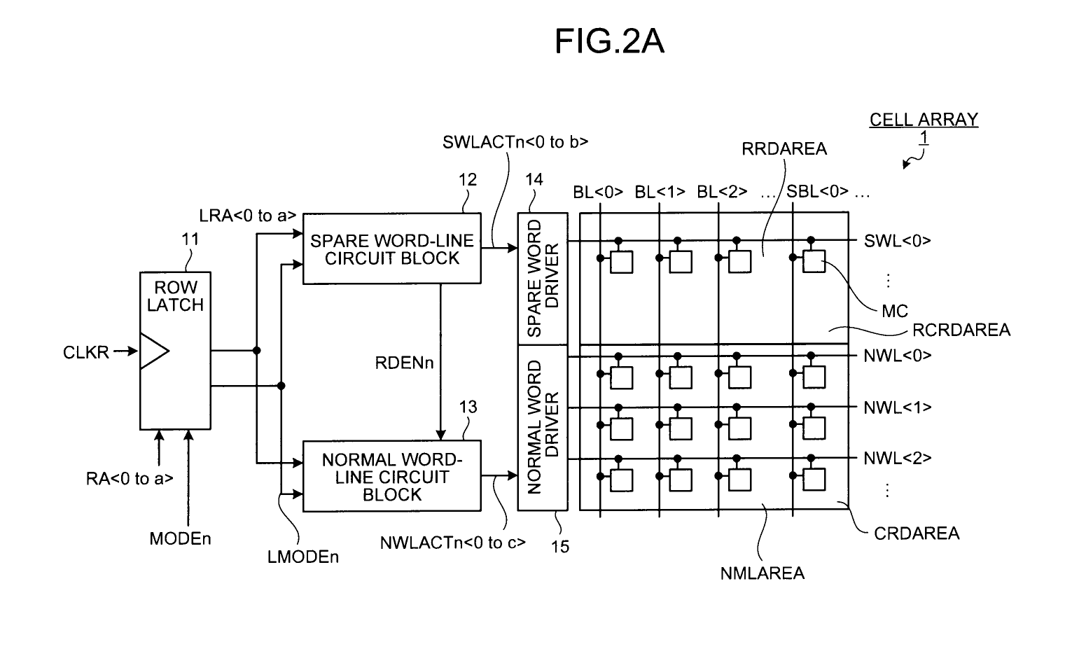

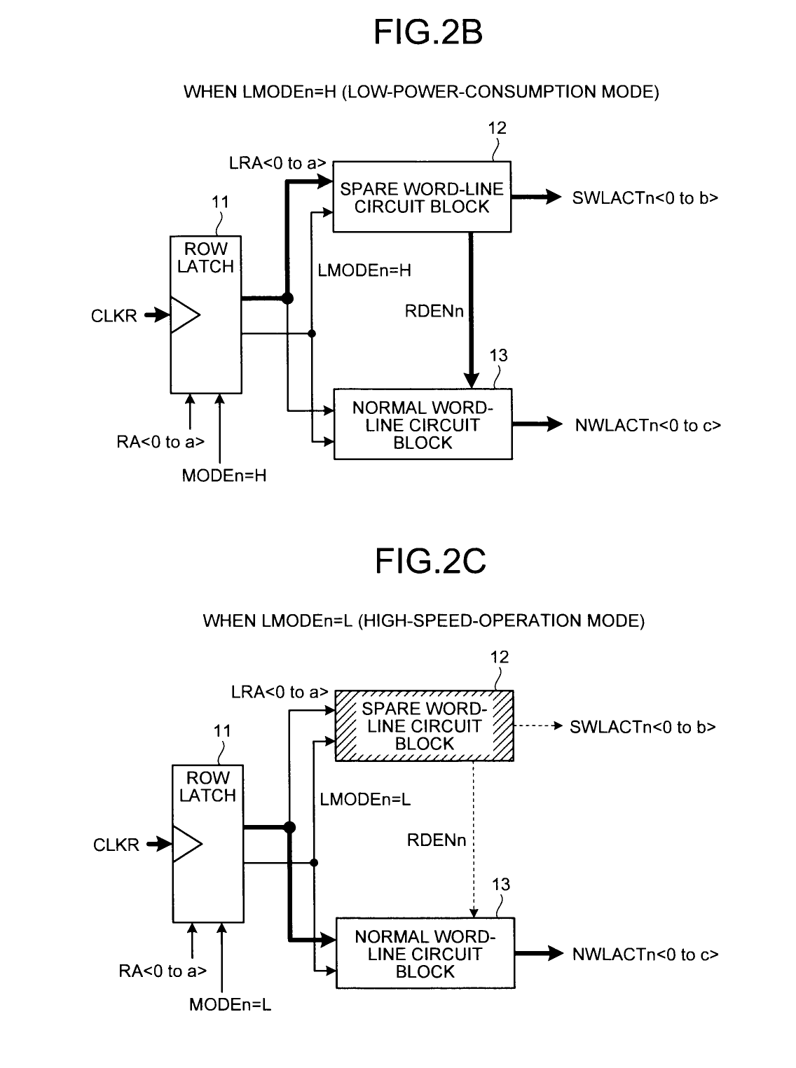

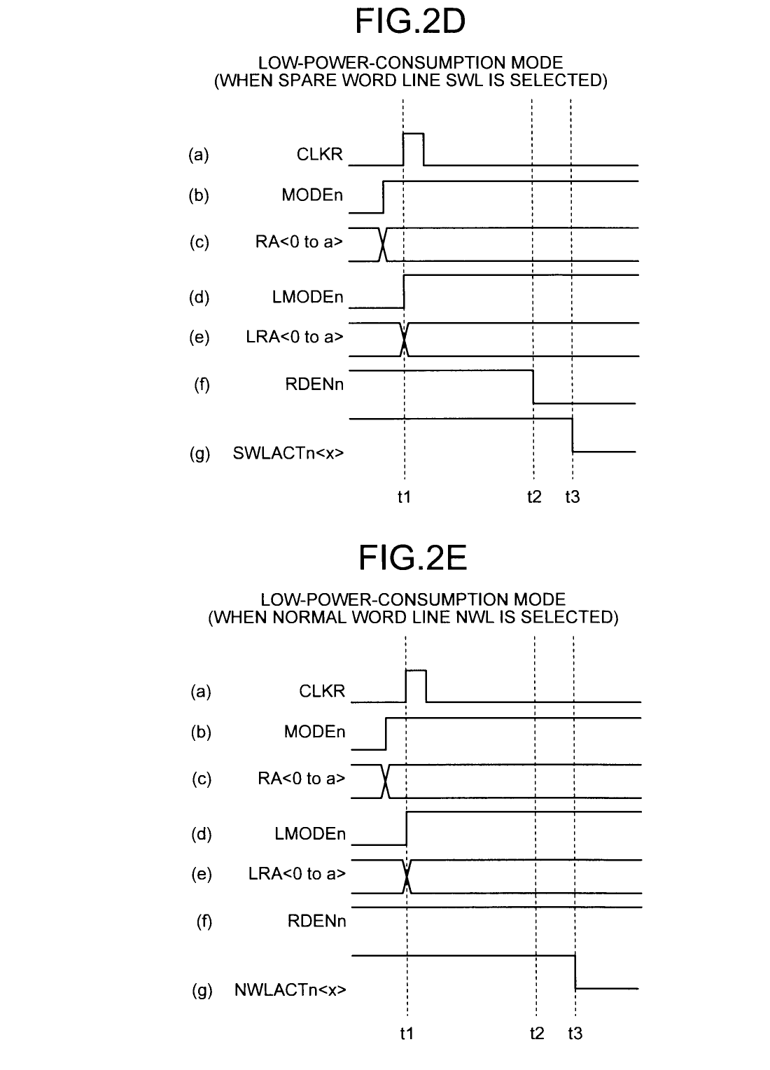

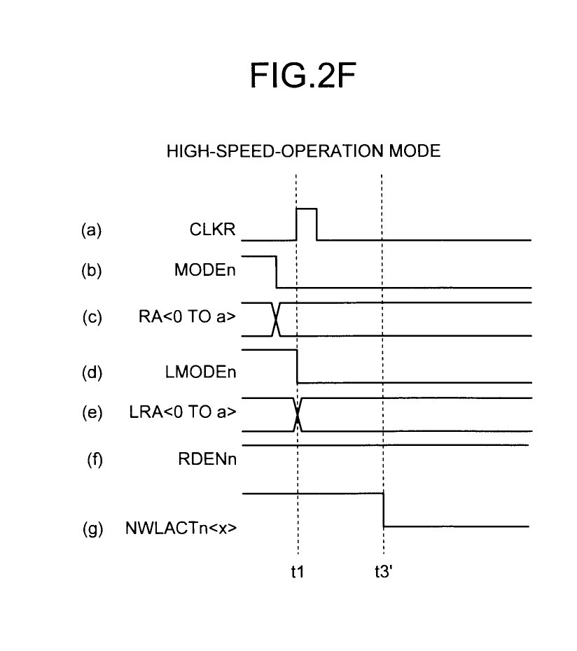

A row path of the semiconductor storage device shown in FIG. 1A is described below with reference to FIGS. 2A to 2F. FIG. 2A is a diagram of a detailed configuration of the row path of the semiconductor storage device shown in FIG. 1A. In FIG. 2A, a column path is not illustrated for simplicity of explanation.

As shown in FIG. 2A, the row path of the semiconductor storage device includes a row latch 11, a spare word-line circuit block 12, and a normal word-line circuit block 13.

The cell array 1 includes memory cells MC, normal bit lines BL, spare bit lines SBL, normal word lines NWL, spare word lines SWL, a spare word driver 14, and a normal word driver 15.

The spare word lines SWL are used for selecting a memory cell MC contained in a row redundancy area RRDAREA and a row column redundancy area RCRDAREA. The normal word lines NWL are used for selecting a memory cell MC contained in a normal area NMLAREA and a column redundancy area CRDAREA.

The spare bit lines SBL are used for selecting each of the memory cells MC contained in the column redundancy area CRDAREA and the row column redundancy area RCRDAREA. The normal bit lines BL are used for selecting each of the memory cells MC contained in the normal area NMLAREA and the row redundancy area RRDAREA.

The spare word driver 14 drives the spare word lines SWL based on a spare word-line activation signal SWLACTn. The normal word driver 15 drives the normal word lines NWL based on a normal word-line activation signal NWLACTn.

The row latch 11 latches a row address RA and a mode selection signal MODEn in synchronization with a row clock CLKR, and outputs the latched row address RA as a local row address LRA and the latched mode selection signal MODEn as a local mode selection signal LMODEn to the spare word-line circuit block 12 and the normal word-line circuit block 13.

The local mode selection signal LMODEn is a signal for controlling whether to use row redundancy and the amount of delay to be added to the normal word-line activation signal NWLACTn.

The spare word-line circuit block 12 is a circuit block for activating the spare word lines SWL. When the local mode selection signal LMODEn=H (i.e., in the low power consumption mode), the spare word-line circuit block 12 compares the input row address RA with a defective row address information. If the input row address RA matches the defective row address information, the spare word-line circuit block 12 activates a redundancy enable signal RDENn to activate only the spare word-line activation signal SWLACTn. On the other hand, if the input row address RA does not match the defective row address information, the spare word-line circuit block 12 deactivates the redundancy enable signal RDENn to activate only the normal word-line activation signal NWLACTn.

The redundancy enable signal RDENn is issued only after the defective row address information and the row address RA are compared with each other. Therefore, a path for issuing the redundancy enable signal RDENn consists of a critical path for determining the tRC of the row path.

On the other hand, the spare word-line circuit block 12 is not used when the local mode selection signal LMODEn=L (i.e., in the high-speed operation mode) (the redundancy enable signal RDENn is not issued).

The normal word-line circuit block 13 is a circuit block for activating the normal word lines NWL by outputting the normal word-line activation signal NWLACTn based on the local row address LRA and the redundancy enable signal RDENn. The normal word-line circuit block 13 changes the amount of delay based on the local mode selection signal LMODEn such that when the local mode selection signal LMODEn=H (i.e., in the low power consumption mode), the normal word-line circuit block 13 sets a sufficient amount of delay for assuring a waiting time for the redundancy enable signal RDENn to be issued. On the other hand, when the local mode selection signal LMODEn=L (i.e., in the high-speed operation mode), the normal word-line circuit block 13 is allowed to activate the normal word-line activation signal NWLACTn without waiting for the redundancy enable signal RDENn to be issued, so that the normal word-line circuit block 13 sets a smaller amount of delay than that in the low power consumption mode.

FIG. 2B is a diagram for explaining operation in the row path of the semiconductor storage device shown in FIG. 2A when the local mode selection signal LMODEn=H (i.e., in the low power consumption mode). Bold lines in FIG. 2B indicate the critical path for the tRC. As described above, because word lines WL are activated after the redundancy enable signal RDENn is issued as a result of comparison between the defective row address information stored in the semiconductor storage device and the local row address LRA, the tRC becomes longer than that obtained when the row redundancy is not used (i.e., in the high-speed operation mode).

FIG. 2C is a diagram for explaining operation in the row path of the semiconductor storage device shown in FIG. 2A when the local mode selection signal LMODEn=L (i.e., in the high-speed operation mode). Bold lines in FIG. 2C indicate the critical path for the tRC.

In the high-speed operation mode, the redundancy enable signal RDENn is not used, so that the normal word lines NWL can be activated without a waiting time for the redundancy enable signal RDENn to be issued. Therefore, the tRC becomes shorter than that obtained when the row redundancy is used (i.e., in the low power consumption mode).

FIG. 2D is a timing diagram for selecting a spare word line SWL in the row path of the semiconductor storage device shown in FIG. 2A in the low power consumption mode (corresponding to the example shown in FIG. 2B).

At time t1, the row latch 11 latches the mode selection signal MODEn and the row address RA in synchronization with the row clock CLKR, and outputs the latched mode selection signal MODEn as the local mode selection signal LMODEn and the latched row address RA as the local row address LRA. At time t2, the redundancy enable signal RDENn is switched to “L” to be activated. Then, at time t3, the spare word-line activation signal SWLACTn is switched to “L” to be activated.

FIG. 2E is a timing diagram for selecting a normal word line NWL in the row path of the semiconductor storage device shown in FIG. 2A in the low power consumption mode (corresponding to the example shown in FIG. 2B).

At time t1, the row latch 11 latches the mode selection signal MODEn and the row address RA in synchronization with the row clock CLKR, and outputs the latched mode selection signal MODEn as the local mode selection signal LMODEn and the latched row address RA as the local row address LRA. At time t2, the redundancy enable signal RDENn is maintained at “H”. Then, at time t3, the normal word-line activation signal NWLACTn is switched to “L” to be activated.

FIG. 2F is a timing diagram of operation in the row path of the semiconductor storage device shown in FIG. 2A in the high-speed operation mode (corresponding to the example shown in FIG. 2C). At time t1, the row latch 11 latches the mode selection signal MODEn and the row address RA in synchronization with the row clock CLKR, and outputs the latched mode selection signal MODEn as the local mode selection signal LMODEn and the latched row address RA as the local row address LRA. At time t3′, the normal word-line activation signal NWLACTn is switched to “L” to be activated. In the high-speed operation mode, because the row redundancy is not used, it is not necessary to wait for the redundancy enable signal RDENn to be issued. Therefore, the normal word-line activation signal NWLACTn can be activated to “L” at a timing earlier than that in the low power consumption mode. In other words, time from latch of the row address RA to issuance of the normal word-line activation signal NWLACTn (i.e., t3′−t1) can be shorter than corresponding time (i.e., t3−t1) in the low power consumption mode as shown in FIG. 2E. As a result, the tRC can be reduced.

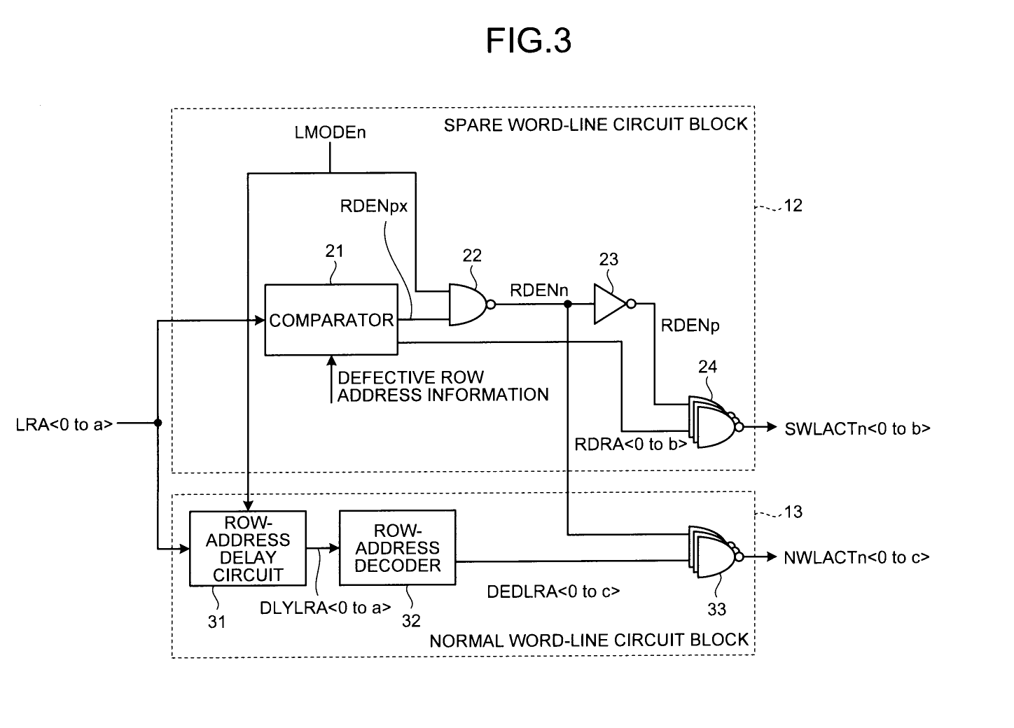

FIG. 3 is a diagram illustrating detailed configurations of the spare word-line circuit block 12 and the normal word-line circuit block 13 shown in FIG. 2A. In FIG. 3, the spare word-line circuit block 12 includes a comparator 21, a NAND gate 22, an inverter 23, and a NAND gate 24. The normal word-line circuit block 13 includes a row-address delay circuit 31, a row-address decoder 32, and a NAND gate 33.

The local row address LRA is input to the comparator 21 and the row-address delay circuit 31. The comparator 21 outputs, when determining that the local row address LRA matches a defective row address information stored in advance in the semiconductor storage device and thereby determining that the local row address LRA needs to be repaired, a hit signal RDENpx to the NAND gate 22. The comparator 21 also outputs a redundancy row address RDRA to the NAND gate 24. The NAND gate 22 outputs a NAND output of the hit signal RDENpx and the local mode selection signal LMODEn as the redundancy enable signal RDENn to the inverter 23 and the NAND gate 33. The inverter 23 outputs a redundancy enable signal RDENp obtained by inverting the redundancy enable signal RDENn to the NAND gate 24. The NAND gate 24 outputs a NAND output of the redundancy enable signal RDENp and the redundancy row address RDRA as the spare word-line activation signal SWLACTn.

The row-address delay circuit 31 outputs the input local row address LRA as a delayed local row address DLYLRA to the row-address decoder 32 after a delay of the amount of delay corresponding to the local mode selection signal LMODEn. The row-address decoder 32 decodes the delayed local row address DLYLRA, and then outputs this delayed local row address DLYLRA as a decoded delayed local row address DEDLRA to the NAND gate 33. The NAND gate 33 outputs a NAND output of the redundancy enable signal RDENn and the decoded delayed local row address DEDLRA as the normal word-line activation signal NWLACTn.

In the low power consumption mode, the local mode selection signal LMODEn=H, so that the hit signal RDENpx is issued as the redundancy enable signal RDENn. On the other hand, in the high-speed operation mode, the local mode selection signal LMODEn=L, the redundancy enable signal RDENn is maintained at “H”.

When the redundancy enable signal RDENn=L, the spare word-line activation signal SWLACTn is switched to “L” to be activated based on the redundancy row address RDRA. On the other hand, when the redundancy enable signal RDENn=H, the row-address delay circuit 31 adds a predetermined amount of delay to the local row address LRA, and the normal word-line activation signal NWLACTn is switched to “L” to be activated based on the decoded delayed local row address DEDLRA that has been decoded by the row-address decoder 32.

Timing when the normal word-line activation signal NWLACTn is switched to “L” for activation is changed between the low power consumption mode and the high-speed operation mode. In the low power consumption mode, the row-address delay circuit 31 sets a sufficient amount of delay for assuring a waiting time for the redundancy enable signal RDENn to be issued. Therefore, the row-address decoder 32 issues the decoded delayed local row address DEDLRA after the redundancy enable signal RDENn is issued. On the other hand, in the high-speed operation mode, the normal word-line activation signal NWLACTn can be activated without a waiting time for the redundancy enable signal RDENn to be issued, so that the row-address delay circuit 31 sets a smaller amount of delay than that in the low power consumption mode.

As described above, the row pass of the semiconductor storage device according to the embodiment includes the row-address delay circuit 31 that changes the timing of activating the normal word-line activation signal NWLACTn (i.e., a row control signal for selecting a word line) between the low power consumption mode and the high-speed operation mode. Therefore, the tRC in the high-speed operation mode can be reduced compared to the tRC in the low power consumption mode.

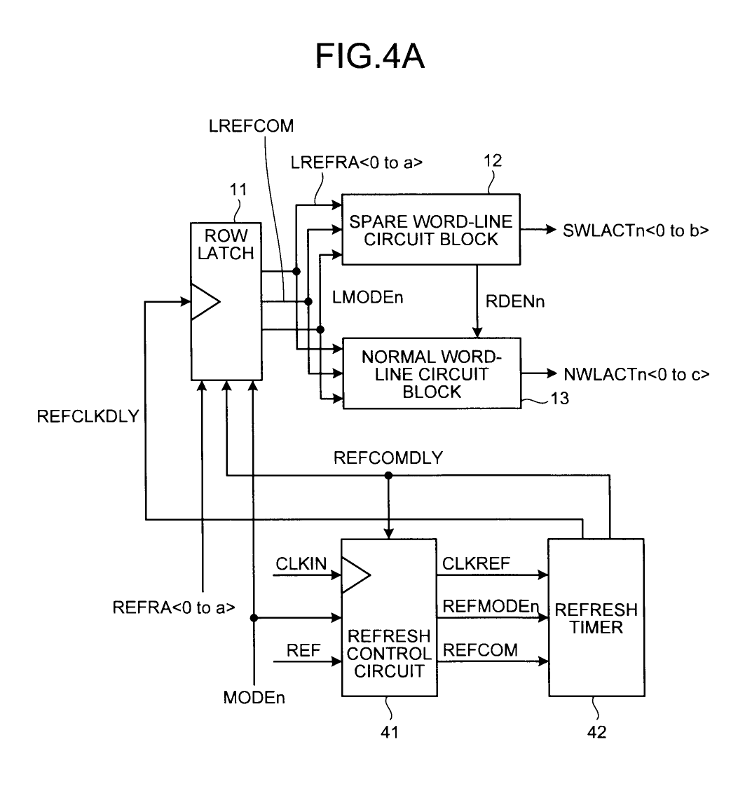

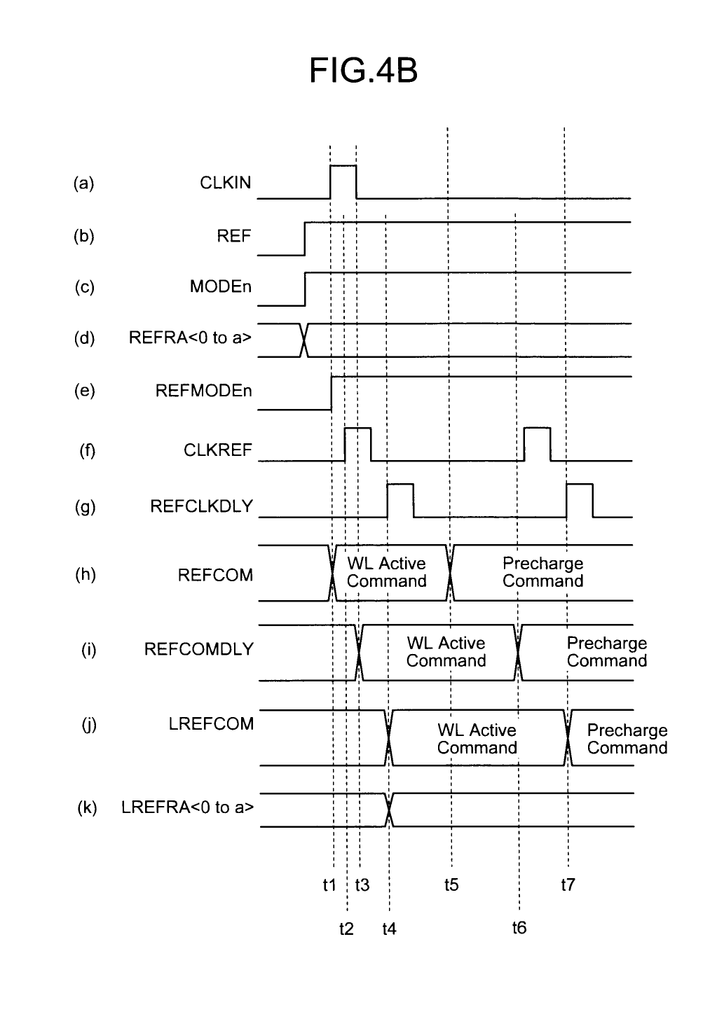

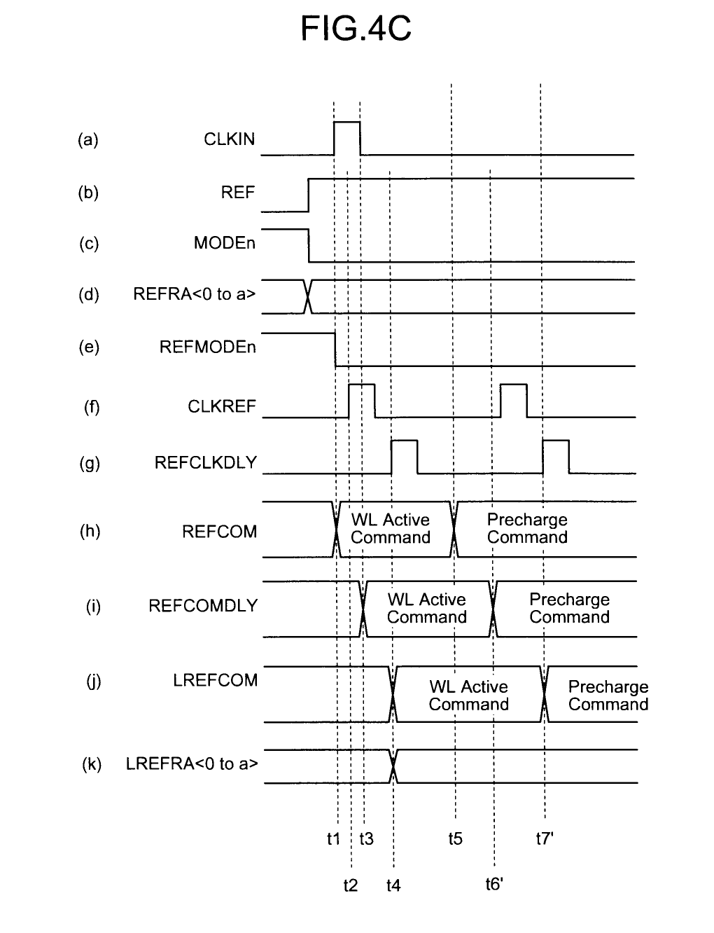

Refresh control performed by the semiconductor storage device according to the embodiment is described below with reference to FIGS. 4A to 4C. FIG. 4A is a diagram of a circuit that performs refresh control in the semiconductor storage device according to the embodiment. As shown in FIG. 4A, the semiconductor storage device includes a refresh control circuit 41 and a refresh timer 42.

The refresh control circuit 41 latches, in synchronization with an external clock CLKIN, a refresh signal REF and the mode selection signal MODEn that are input from an external apparatus. Then, the refresh control circuit 41 generates a refresh clock CLKREF, a refresh command REFCOM, and a refresh mode selection signal REFMODEn, and outputs them to the refresh timer 42. The refresh mode selection signal REFMODEn is only latched by the refresh control circuit 41, so that the refresh mode selection signal REFMODEn is practically the same as the mode selection signal MODEn.

The refresh timer 42 sets the amount of delay based on the refresh mode selection signal REFMODEn. Then, the refresh timer 42 outputs, to the row latch 11, a delayed refresh clock REFCLKDLY and a delayed refresh command REFCOMDLY that are obtained by delaying the refresh clock CLKREF and the refresh command REFCOM, respectively, by the set amount of delay.

The row latch 11 latches an input refresh row address REFRA, the mode selection signal MODEn, and the delayed refresh command REFCOMDLY in synchronization with the delayed refresh clock REFCLKDLY. Then, the row latch 11 outputs a local refresh row address LREFRA, the local mode selection signal LMODEn, and a local refresh command LREFCOM to the spare word-line circuit block 12 and the normal word-line circuit block 13.

The delayed refresh command REFCOMDLY output from the refresh timer 42 is also input to the refresh control circuit 41, and used for generating the refresh command REFCOM. By changing a timing of issuing the delayed refresh command REFCOMDLY, a refresh row cycle tRCREF in the high-speed operation mode can be reduced compared to a refresh row cycle tRCREF in the low power consumption mode.

FIG. 4B is a timing diagram of operation performed by the semiconductor storage device shown in FIG. 4A in the low power consumption mode.

At time t1, the refresh control circuit 41 latches, in synchronization with the external clock CLKIN, the refresh signal REF and the mode selection signal MODEn that are input from an external apparatus, and then outputs a word-line active command as the refresh command REFCOM. At time t2, the refresh control circuit 41 outputs the first refresh clock CLKREF. The refresh timer 42 adds a delay corresponding to t3−t1 to the word-line active command output as the refresh command REFCOM, and then outputs the word-line active command as the delayed refresh command REFCOMDLY to the row latch 11.

The refresh timer 42 also adds a delay corresponding to t4−t2 to the first refresh clock CLKREF, and then outputs the first delayed refresh clock REFCLKDLY. The row latch 11 latches the word-line active command that has been issued as the delayed refresh command REFCOMDLY and the refresh row address REFRA, in synchronization with the first delayed refresh clock REFCLKDLY.

At time t5, the refresh control circuit 41 receives the word-line active command output as the delayed refresh command REFCOMDLY, and then outputs a precharge command as the refresh command REFCOM. The refresh timer 42 adds a delay corresponding to t6−t5 to the precharge command that has been issued as the refresh command REFCOM, and then outputs this precharge command as the delayed refresh command REFCOMDLY to the row latch 11 at time t6.

The second refresh clock CLKREF is output according to outputting of the precharge command issued as the delayed refresh command REFCOMDLY. The refresh timer 42 adds the same amount of delay as the first refresh clock CLKREF to the second refresh clock CLKREF, and issues this second refresh clock CLKREF as the second delayed refresh clock REFCLKDLY. Then, at time t7, the row latch 11 latches the precharge command that has been issued as the delayed refresh command REFCOMDLY in synchronization with the second delayed refresh clock REFCLKDLY.

FIG. 4C is a timing diagram of operation performed by the semiconductor storage device shown in FIG. 4A in the high-speed operation mode. In FIG. 4C, in the high-speed operation mode, the precharge command to be issued as the delayed refresh command REFCOMDLY is issued at time t6′ that is earlier than a corresponding timing in the low power consumption mode as shown in FIG. 4B. The reason being that the redundancy path is not used in the row path on a downstream side of the row latch 11, so that the word lines can be activated at a timing earlier than that in the low power consumption mode. Then, at time t7′, the row latch 11 latches the precharge command that has been issued as the delayed refresh command REFCOMDLY in synchronization with the delayed refresh clock REFCLKDLY.

As described above, a refresh control system of the semiconductor storage device according to the embodiment includes the refresh control circuit 41 that generates the refresh control signal (i.e., the refresh command REFCOM and the refresh mode selection signal REFMODEn) and the refresh timer 42 that changes the amount of delay of the refresh control signal between the low power consumption mode and the high-speed operation mode. Therefore, the tRCREF in the high-speed operation mode can be reduced compared to the tRCREF in the low power consumption mode.

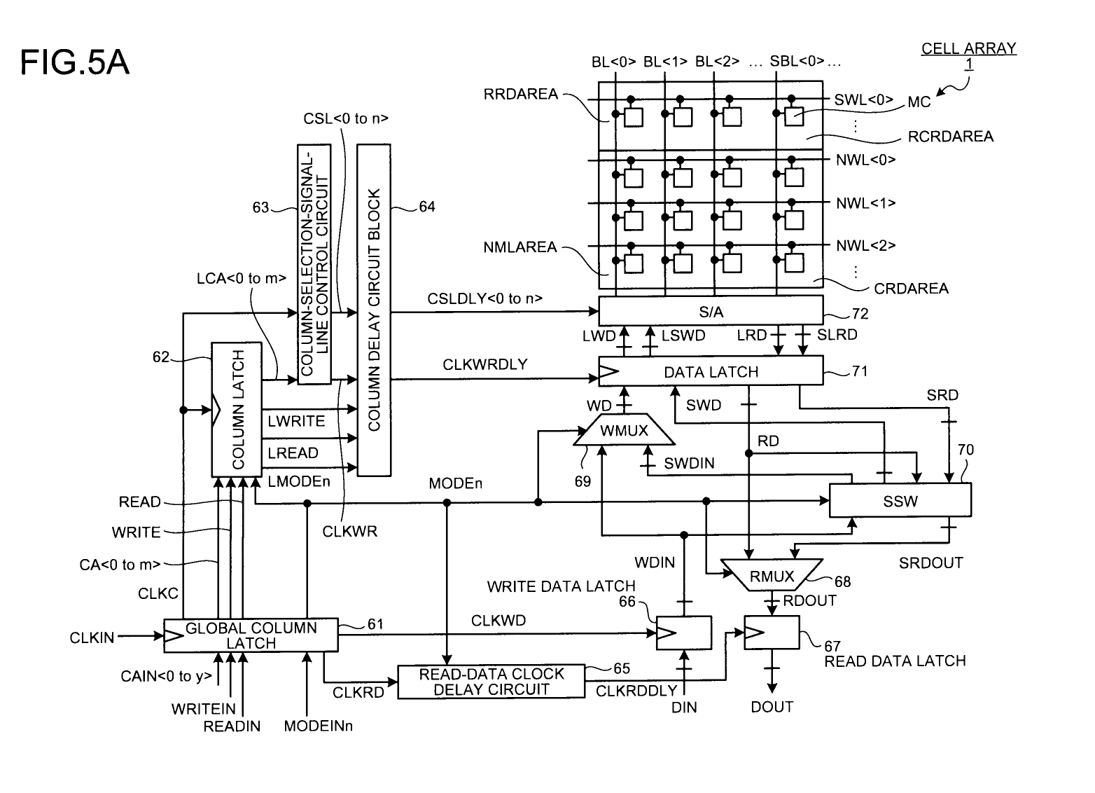

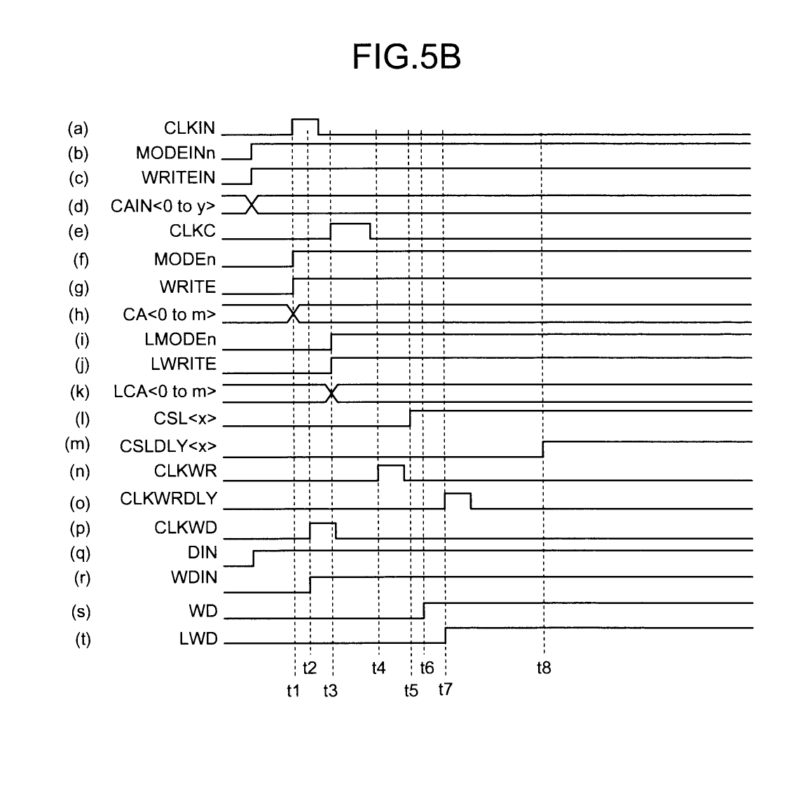

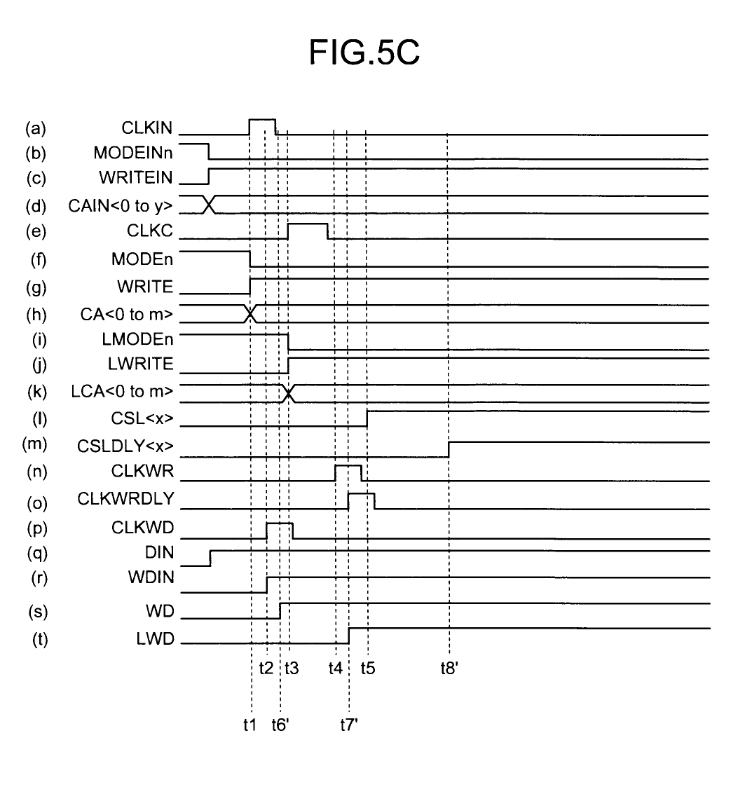

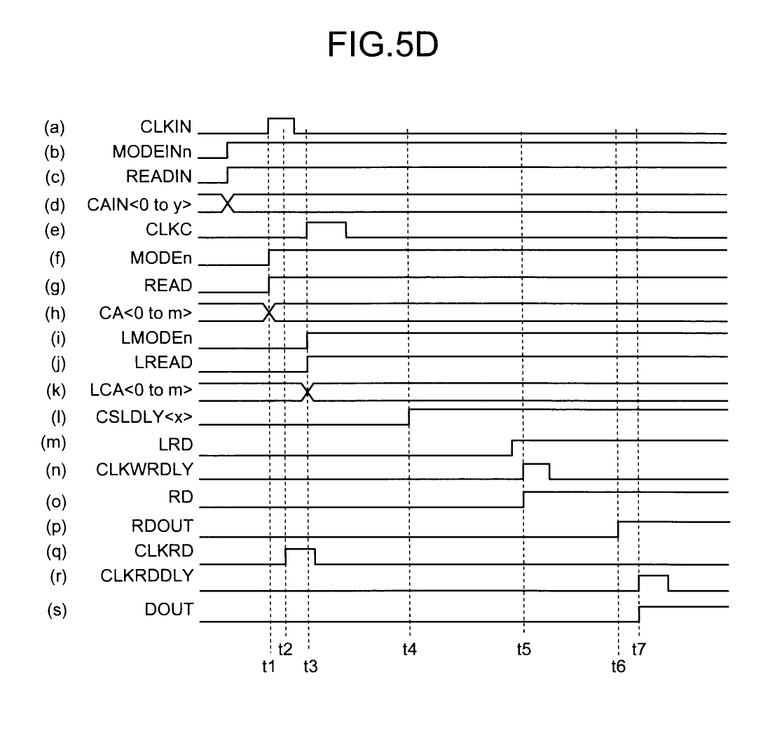

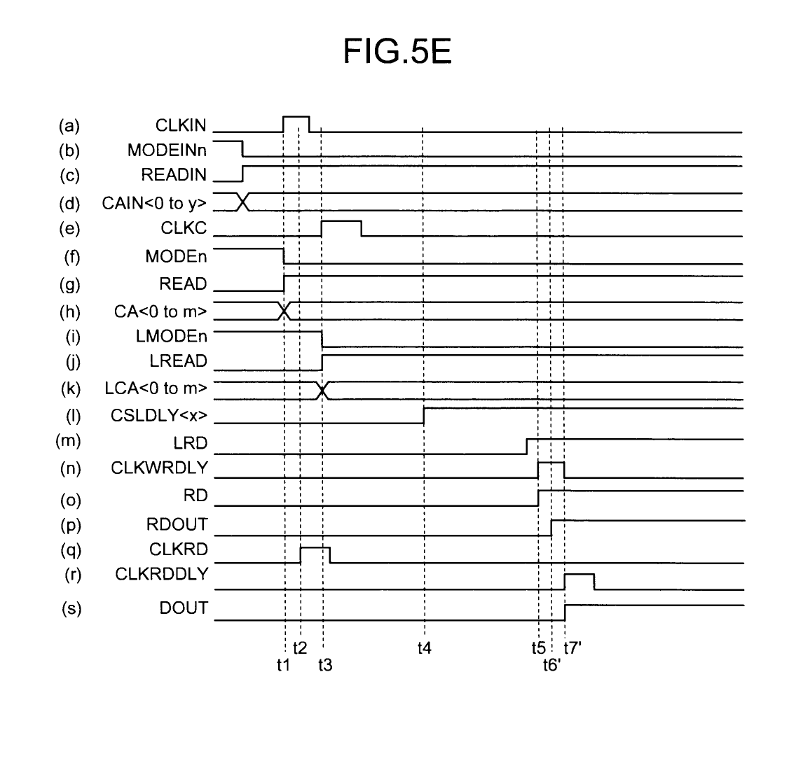

A column path of the semiconductor storage device shown in FIG. 1A is described below with reference to FIGS. 5A to 5E. FIG. 5A is a diagram of a detailed configuration of the column path of the semiconductor storage device shown in FIG. 1A. In FIG. 5A, the row path is not illustrated for simplicity of explanation.

As shown in FIG. 5A, the column path of the semiconductor storage device includes a global column latch 61, a column latch 62, a column-selection-signal-line control circuit 63, a column delay circuit block 64, a read-data clock delay circuit 65, a write data latch 66, a read data latch 67, a read multiplexer (RMUX) 68, a write multiplexer (WMUX) 69, a shift switch (SSW) 70, a data latch 71, and a sense amplifier (S/A) 72.

The SSW 70 functions as a redundancy-line selection circuit that controls selection of a spare bit line SBL in a column shift redundancy system. When the column shift redundancy system is employed, it is necessary to guide data to pass through the SSW 70. Therefore, extra time is necessary to guide the data to pass through the SSW 70, leading to increased tRC. As a result, performance of the semiconductor storage device degrades. To resolve such a problem, both the low power consumption mode with the redundancy and the high-speed operation mode without the redundancy are employed in the semiconductor storage device as described below.

The global column latch 61 latches an input column address CAIN, an input write signal WRITEIN, an input read signal READIN, and an input mode selection signal MODEINn in synchronization with the external input clock CLKIN. Then, the global column latch 61 outputs the external input clock CLKIN as a column clock CLKC, the latched input column address CAIN as a column address CA, the latched input write signal WRITEIN as a write signal WRITE, the latched input read signal READIN as a read signal READ, and the latched input mode selection signal MODEINn as the mode selection signal MODEn. The global column latch 61 also outputs a write data clock CLKWD and a read data clock CLKRD.

The column latch 62 latches the column address CA, the write signal WRITE, the read signal READ, and the mode selection signal MODEn in synchronization with the column clock CLKC. Then, the column latch 62 outputs the latched column address CA as a local column address LCA to the column-selection-signal-line control circuit 63. Furthermore, the column latch 62 outputs the latched write signal WRITE as a local write signal LWRITE, the latched read signal READ as a local read signal LREAD, and the latched mode selection signal MODEn as the local mode selection signal LMODEn to the column delay circuit block 64.

The column-selection-signal-line control circuit 63 receives the local column address LCA and the column clock CLKC, and then outputs a column selection signal CSL and a write-read clock CLKWR to the column delay circuit block 64.

The column delay circuit block 64 changes the amount of delay to be added to the column selection signal CSL and the write-read clock CLKWR based on the local write signal LWRITE and the local read signal LREAD that are input to the column delay circuit block 64. The column delay circuit block 64 changes the amount of delay based also on the local mode selection signal LMODEn that is input to the column delay circuit block 64. Thus, the column delay circuit block 64 changes the amount of delay not only between the write operation and the read operation but also between the low power consumption mode and the high-speed operation mode.

The column delay circuit block 64 delays the write-read clock CLKWR, and then outputs this write-read clock CLKWR as a delayed write-read clock CLKWRDLY to the data latch 71. The column delay circuit block 64 also delays the column selection signal CSL, and then outputs this column selection signal CSL as a delayed column selection signal CSLDLY to the S/A 72.

In write operation, the write data latch 66 latches input data DIN in synchronization with the write data clock CLKWD, and outputs the latched input data DIN as input write data WDIN to the SSW 70 and the WMUX 69. The WMUX 69 also receives shift input write data SWDIN output from the SSW 70.

The WMUX 69 selects, when the mode selection signal MODEn=L (i.e., in the high-speed operation mode), the input write data WDIN, and outputs the input write data WDIN as write data WD to the data latch 71. On the other hand, when the mode selection signal MODEn=H (i.e., in the low power consumption mode), the WMUX 69 selects the shift input write data SWDIN, and outputs the shift input write data SWDIN as the write data WD to the data latch 71. If the SSW 70 outputs the shift input write data SWDIN as spare write data SWD through connection to the spare write data line, it is not necessary to guide the spare write data SWD to pass through the WMUX 69, so that the spare write data SWD is directly output to the data latch 71.

The data latch 71 latches the write data WD and the spare write data SWD in synchronization with the delayed write-read clock CLKWRDLY, and outputs the latched write data WD as local write data LWD and the latched spare write data SWD as local spare write data LSWD to the S/A 72. The S/A 72 writes, at the same time when the delayed column selection signal CSLDLY is activated, the local write data LWD to a memory cell MC via the normal bit line BL, and the spare write data SWD to a memory cell MC via the spare bit line SBL.

In read operation, the S/A 72 amplifies data readout from a memory cell MC connected to the normal bit line BL as local read data LRD, and amplifies data readout from a memory cell MC connected to the spare bit line SBL as local spare read data SLRD. Then, the data latch 71 latches the local read data LRD and the local spare read data SLRD in synchronization with the delayed write-read clock CLKWRDLY.

The data latch 71 outputs read data RD and spare read data SRD received from the data latch 71 as shift output read data SRDOUT to the RMUX 68 by shifting a connection of a data line.

The RMUX 68 selects, when the mode selection signal MODEn=L (i.e., in the high-speed operation mode), the read data RD, and outputs the read data RD as output read data RDOUT. On the other hand, when the mode selection signal MODEn=H (i.e., in the low power consumption mode), the RMUX 68 selects the shift output read data SRDOUT, and outputs the shift output read data SRDOUT as the output read data RDOUT.

The read-data clock delay circuit 65 receives the read data clock CLKRD and the mode selection signal MODEn from the global column latch 61, and changes the amount of delay based on the mode selection signal MODEn. The read-data clock delay circuit 65 delays the read data clock CLKRD by the set amount of delay, and then outputs this read data clock CLKRD as a delayed read data clock CLKRDDLY to the read data latch 67. The read data latch 67 latches the output read data RDOUT in synchronization with the delayed read data clock CLKRDDLY, and outputs the latched output read data RDOUT as output data DOUT to outside of the memory.

FIG. 5B is a timing diagram of write operation in the column path of the semiconductor storage device shown in FIG. 5A in the low power consumption mode.

At time t1, the global column latch 61 latches the input column address CAIN, the input write signal WRITEIN, and the input mode selection signal MODEINn in synchronization with the external input clock CLKIN, and outputs the latched the input column address CAIN as the column address CA, the latched input write signal WRITEIN as the write signal WRITE, and the latched input mode selection signal MODEINn as the mode selection signal MODEn. At time t2, the write data latch 66 latches the input data DIN in synchronization with the write data clock CLKWD output from the global column latch 61.

At time t3, the column latch 62 latches the column address CA, the write signal WRITE, and the mode selection signal MODEn in synchronization with the column clock CLKC output from the global column latch 61, and outputs the latched column address CA as the local column address LCA, the latched write signal WRITE as the local write signal LWRITE, and the latched mode selection signal MODEn as the local mode selection signal LMODEn to the column delay circuit block 64.

At time t4, the column-selection-signal-line control circuit 63 outputs the write-read clock CLKWR to the column delay circuit block 64, and then the column delay circuit block 64 adds a delay corresponding to t7−t4 to the write-read clock CLKWR. The column delay circuit block 64 outputs the delayed write-read clock CLKWRDLY at time t7.

At time t5, the column-selection-signal-line control circuit 63 outputs the column selection signal CSL, and then the column delay circuit block 64 adds a delay corresponding to t8−t5 to the column selection signal CSL. The column delay circuit block 64 outputs the delayed column selection signal. CSLDLY at time t8. At time t6, the SSW 70 shifts a data line and then outputs the write data WD. At time t7, the data latch 71 latches the write data WD in synchronization with the delayed write-read clock CLKWRDLY, and then outputs the local write data LWD.

FIG. 5C is a timing diagram of write operation in the column path of the semiconductor storage device shown in FIG. 5A in the high-speed operation mode. At time t6′, the write data WD has not passed through the SSW 70, so that the write data WD is fixed at a timing earlier than that in the low power consumption mode. At time t4, the write-read clock CLKWR is output, and then the column delay circuit block 64 adds a delay corresponding to t7′−t4 (<t7−t4: see FIG. 5B) to the write-read clock CLKWR. Then, the column delay circuit block 64 outputs the delayed write-read clock CLKWRDLY at time t7′. At time t5, the column selection signal CSL is output, and then the column delay circuit block 64 adds a delay corresponding to t8′−t5 (<t8−t5: see FIG. 5B) to the column selection signal CSL. Then, the column delay circuit block 64 outputs the delayed column selection signal CSLDLY at time t8′. At time t7′, the data latch 71 latches the write data WD in synchronization with the delayed write-read clock CLKWRDLY, and then outputs the local write data LWD.

FIG. 5D is a timing diagram of read operation in the column path of the semiconductor storage device shown in FIG. 5A in the low power consumption mode.

At time t1, the global column latch 61 latches the input column address CAIN, the input read signal READIN, and the input mode selection signal MODEINn in synchronization with the external input clock CLKIN, and outputs the latched input column address CAIN as the column address CA, the latched input read signal READIN as the read signal READ, and the latched input mode selection signal MODEINn as the mode selection signal MODEn. At time t2, the global column latch 61 outputs the read data clock CLKRD. At time t3, the column latch 62 latches the column address CA, the read signal READ, and the mode selection signal MODEn in synchronization with the column clock CLKC output from the global column latch 61, and outputs the latched column address CA as the local column address LCA, the latched read signal READ as the local read signal LREAD, and the latched mode selection signal MODEn as the local mode selection signal LMODEn to the column delay circuit block 64.

At time t4, the delayed column selection signal CSLDLY is output. At time t5, the data latch 71 latches the local read data LRD in synchronization with the delayed write-read clock CLKWRDLY, and outputs the latched local read data LRD as the read data RD. At time t6, the output read data RDOUT is fixed after passing through the SSW 70. At time t7, the read data latch 67 latches the output read data RDOUT in synchronization with the delayed read data clock CLKRDDLY, and outputs the latched output read data RDOUT as the output data DOUT to the outside of the memory. The read-data clock delay circuit 65 adds a delay corresponding to t7−t2 to the read data clock CLKRD.

FIG. 5E is a timing diagram of read operation in the column path of the semiconductor storage device shown in FIG. 5A in the high-speed operation mode. Operation performed from time t1 to time t5 is the same as that performed in the low power consumption mode as shown in FIG. 5D. In the high-speed operation mode, it is not necessary to guide the data to pass through the SSW 70, so that the output read data RDOUT can be fixed at time t6′ that is earlier than a corresponding timing in the low power consumption mode. More specifically, t6′−t5<t6−t5 (see FIG. 5D). Therefore, the delayed read data clock CLKRDDLY can be output at an earlier timing. The read-data clock delay circuit 65 adds a delay corresponding to t7′−t2 (<t7−t2: see FIG. 5D) to the read data clock CLKRD. Then, at time t7′, the read data latch 67 latches the output read data RDOUT in synchronization with the delayed read data clock CLKRDDLY, and outputs the latched output read data RDOUT as the output data DOUT to the outside of the memory.

As described above, the column path of the semiconductor storage device according to the embodiment includes the column delay circuit block 64 that changes, between the low power consumption mode and the high-speed operation mode, the amount of delay to be added to the column selection signal CSL (a column control signal) for selecting a bit line in the write operation, and the read-data clock delay circuit 65 that changes, between the low power consumption mode and the high-speed operation mode, the amount of delay to be added to the read clock CLKRD for latching the output read data RDOUT in the read operation. Therefore, the tRC in the high-speed operation mode can be reduced compared to the tRC in the low power consumption mode.

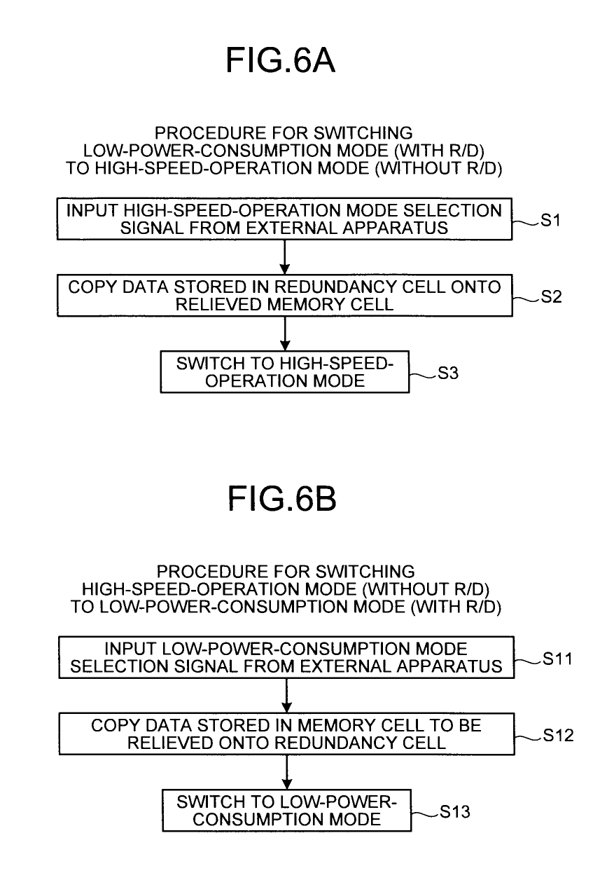

A procedure for switching a mode from the low power consumption mode to the high-speed operation mode is described below with reference to FIGS. 6A to 10.

FIG. 6A is a diagram illustrating a procedure for switching the low power consumption mode with redundancy to the high-speed operation mode without the redundancy. In FIG. 6A, when, in the low power consumption mode in which the redundancy is used, a high-speed operation mode selection signal (i.e., the input mode selection signal MODEINn=L) is input from an external apparatus (Step S1), the semiconductor storage device copies data in a redundancy cell onto a relieved memory cell (Step S2), and switches the low power consumption mode to the high-speed operation mode in which the redundancy is not used (Step S3).

FIG. 6B is a diagram illustrating a procedure for switching the high-speed operation mode without the redundancy to the low power consumption mode with the redundancy. In FIG. 6B, when, in the high-speed operation mode in which the redundancy is not used, a low power consumption mode selection signal (i.e., the input mode selection signal MODEINn=H) is input from an external apparatus (Step S11), the semiconductor storage device copies data in a memory cell to be repaired to a redundancy cell (Step S12), and switches the high-speed operation mode to the low power consumption mode in which the redundancy is used (Step S13).

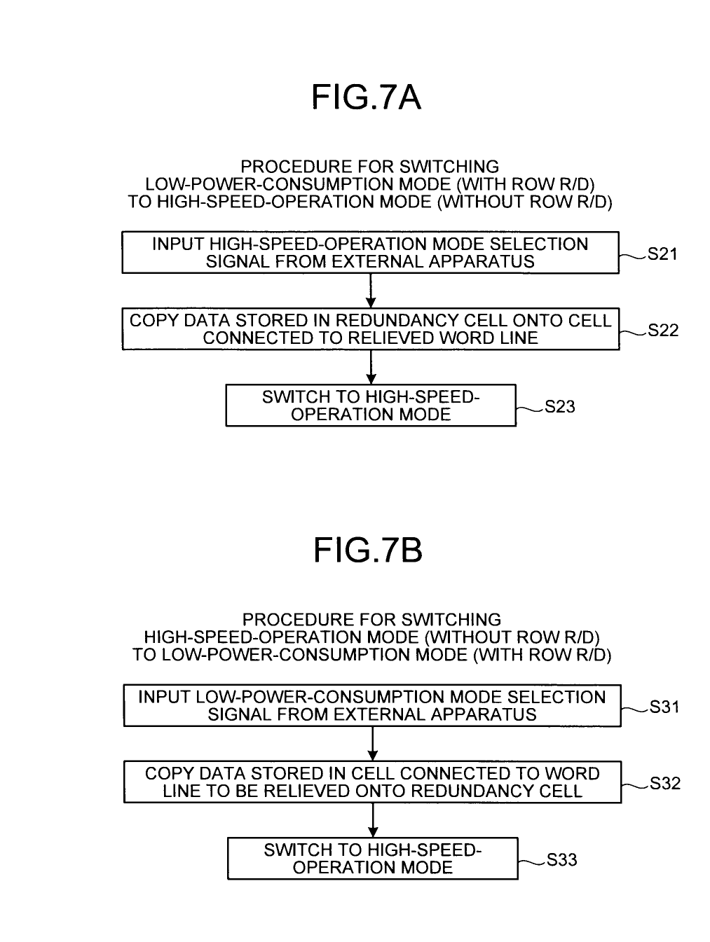

FIG. 7A is a diagram illustrating a procedure for switching the low power consumption mode with row redundancy to the high-speed operation mode without the row redundancy. In FIG. 7A, when, in the low power consumption mode in which the row redundancy is used, the high-speed operation mode selection signal (i.e., the input mode selection signal MODEINn=L) is input from an external apparatus (Step S21), the semiconductor storage device copies data in a redundancy cell onto a cell connected to a relieved word line (Step S22), and switches the low power consumption mode to the high-speed operation mode in which the row redundancy is not used (Step S23).

FIG. 7B is a diagram illustrating a procedure for switching the high-speed operation mode without the row redundancy to the low power consumption mode with the row redundancy. In FIG. 7B, when, in the high-speed operation mode in which the row redundancy is not used, the low power consumption mode selection signal (i.e., the input mode selection signal MODEINn=H) is input from an external apparatus (Step S31), the semiconductor storage device copies data in a cell connected to a word line to be relieved onto a redundancy cell (Step S32), and switches the high-speed operation mode to the low power consumption mode in which the row redundancy is used (Step S33).

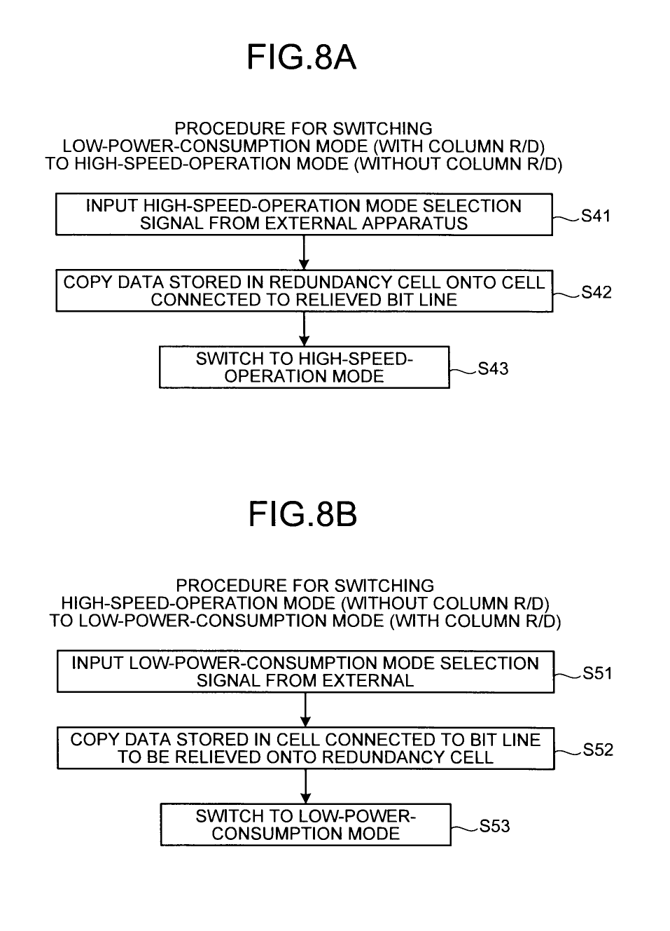

FIG. 8A is a diagram illustrating a procedure for switching the low power consumption mode with column redundancy to the high-speed operation mode without the column redundancy. In FIG. 8A, when, in the low power consumption mode in which the column redundancy is used, the high-speed operation mode selection signal (i.e., the input mode selection signal MODEINn=L) is input from an external apparatus (Step S41), the semiconductor storage device copies data in a redundancy cell onto a cell connected to a relieved bit line (Step S42), and switches the low power consumption mode to the high-speed operation mode in which the column redundancy is not used (Step S43).

FIG. 8B is a diagram illustrating a procedure for switching the high-speed operation mode without the column redundancy to the low power consumption mode with the column redundancy. In FIG. 8B, when, in the high-speed operation mode in which the column redundancy is not used, the low power consumption mode selection signal (i.e., the input mode selection signal MODEINn=H) is input from an external apparatus (Step S51), the semiconductor storage device copies data in a cell connected to a bit line to be relieved onto a redundancy cell (Step S52), and switches the high-speed operation mode to the low power consumption mode in which the column redundancy is used (Step S53).

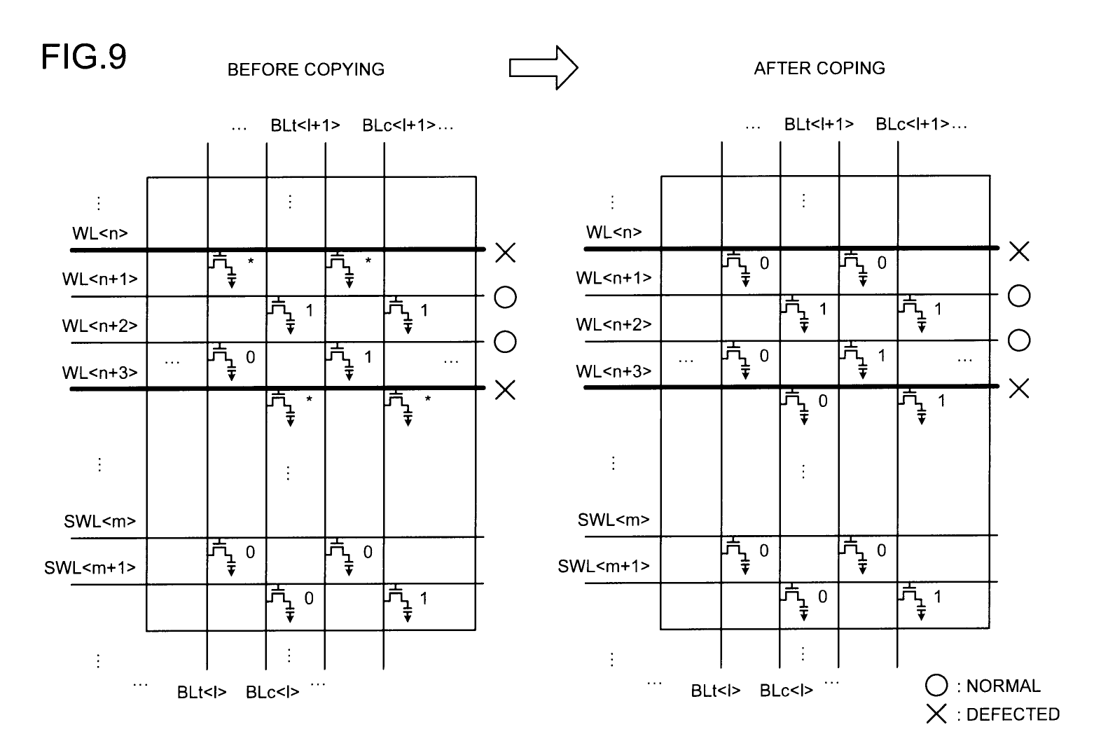

FIG. 9 is a schematic diagram for explaining how data is copied when the low power consumption mode is switched to the high-speed operation mode. In FIG. 9, a DRAM is used as an example. In a state before copying shown in FIG. 9, it is assumed that memory cells connected to normal word lines WL<n> and WL<n+3> are relieved with memory cells connected to spare word lines SWL<m> and SWL<m+1>, respectively. Data stored in the cells connected to the spare word lines SWL<m> and SWL<m+1> is copied to the memory cells connected to the normal word lines WL<n> and WL<n+3> that have been repaired. It is also assumed that the memory cells connected to the normal word lines WL<n> and WL<n+3> contain a cell in which retention failure has occurred, which is to be relieved in the low power consumption mode.

In a state after copying, the data stored in the memory cells connected to the spare word line SWL<m> is equal to the data stored in the memory cells connected to the normal word line WL<n>. Similarly, the data stored in the memory cells connected to the spare word line SWL<m+1> is equal to the data stored in the memory cells connected to the normal word line <n+3>. Therefore, in the high-speed operation mode, data-read and data-write can be enabled without the redundancy.

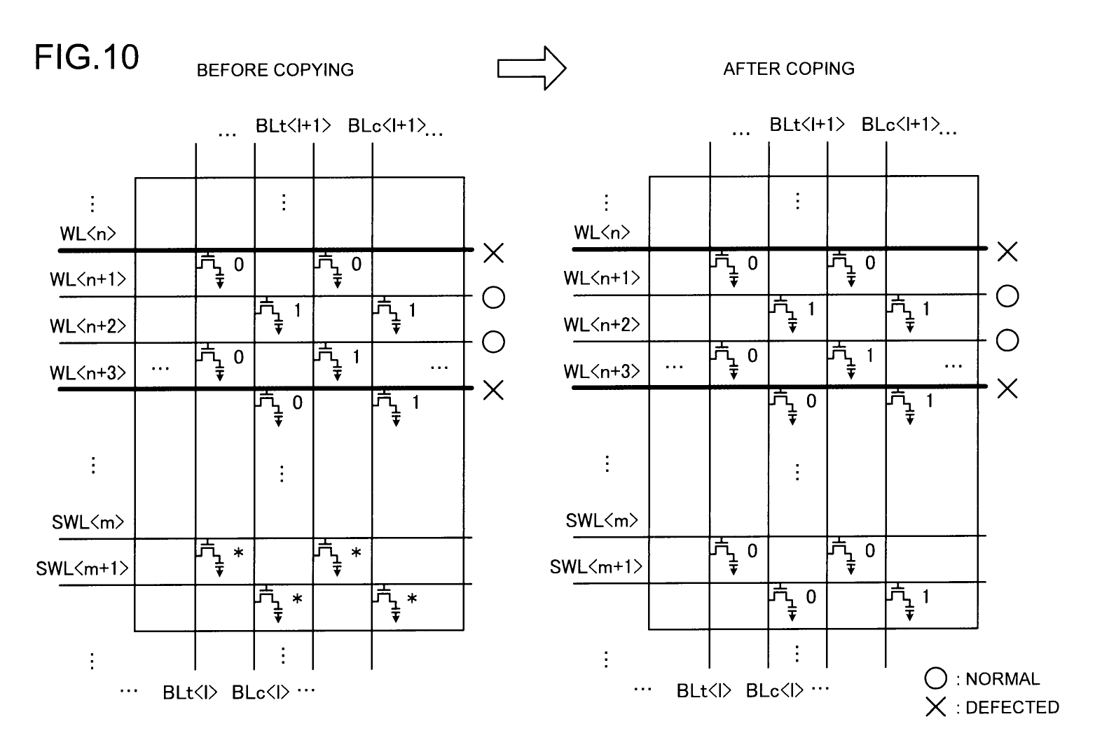

FIG. 10 is a schematic diagram for explaining how data is copied when the high-speed operation mode is switched to the low power consumption mode. In FIG. 10, a DRAM is used as an example. In a state before copying shown in FIG. 10, it is assumed that memory cells connected to the normal word lines WL<n> and WL<n+3> that are to be relieved in the low power consumption mode are being used. Data stored in the memory cells connected to the normal word lines WL<n> and WL<n+3> is copied to memory cells connected to the spare word lines SWL<m> and SWL<m+1>. It is also assumed that the memory cells connected to the normal word lines WL<n> and WL<n+3> contain a memory cell in which retention failure has occurred that is to be relieved in the low power consumption mode.

In a state after copying, the data stored in the memory cells connected to the spare word line SWL<m> is equal to the data stored in the memory cells connected to the normal word line WL<n>. Similarly, the data stored in the memory cells connected to the spare word line SWL<m+1> is equal to the data stored in the memory cells connected to the normal word line <n+3>. Thus, in the low power consumption mode, the redundancy can be enabled.

As described above, the semiconductor storage device according to the embodiment copies data stored in a memory cell connected to the normal word line WL to a memory cell connected to the spar word line SWL when switching the mode from the high-speed operation mode to the low power consumption mode. Furthermore, the semiconductor storage device copies data stored in a memory cell connected to the spare word line SWL to a memory cell connected to the normal word line WL when switching the mode from the low power consumption mode to the high-speed operation mode. Therefore, it is possible to realize both the low power consumption mode and the high-speed operation mode without losing data that is required to be retained in the semiconductor storage device.

The semiconductor storage device according to the embodiment can be applied to any semiconductor storage devices that employ the redundancy. For example, the semiconductor storage device according to the embodiment can be applied to various RAMs such as a DRAM, an eDRAM, an SRAM, and a FeRAM.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor storage device that includes a normal area having a plurality of memory cells incorporated therein and a redundancy area having a plurality of memory cells incorporated therein, the semiconductor storage device comprising:
a delaying unit that changes, between a first mode in which both the normal area and the redundancy area are used and a second mode in which only the normal area is used without use of the redundancy area, a timing for issuing a cell-array control signal for selecting a memory cell from among the memory cells used in a corresponding mode.

2. The semiconductor storage device according to claim 1, wherein
the redundancy area is a row redundancy area, and
the cell-array control signal is a row control signal for selecting a word line.

3. The semiconductor storage device according to claim 1, wherein
the redundancy area is a column redundancy area, and
the cell-array control signal is a column control signal for selecting a bit line.

4. The semiconductor storage device according to claim 1, further comprising:
a control circuit that generates a refresh control signal; and
a refresh timer that delays the refresh control signal generated by the control circuit, wherein
the refresh timer changes an amount of delay to be added to the refresh control signal between the first mode and the second mode.

5. The semiconductor storage device according to claim 1, wherein
when the first mode is switched to the second mode, data stored in a memory cell in the redundancy area is copied to a memory cell in the normal area, and
when the second mode is switched to the first mode, data stored in a memory cell in the normal area is copied to a memory cell in the redundancy area.

6. A redundancy method implemented by a semiconductor storage device that includes a normal area having a plurality of memory cells incorporated therein and a redundancy area having a plurality of memory cells incorporated therein, the redundancy method comprising:
changing, between a first mode in which both the normal area and the redundancy area are used and a second mode in which only the normal area is used without use of the redundancy area, a timing for issuing a cell-array control signal for selecting a memory cell from among the memory cells used in a corresponding mode.

7. The redundancy method according to claim 6, wherein
the redundancy area is a row redundancy area, and
the cell-array control signal is a row control signal for selecting a word line.

8. The redundancy method according to claim 6, wherein
the redundancy area is a column redundancy area, and
the cell-array control signal is a column control signal for selecting a bit line.

9. The redundancy method according to claim 6, further comprising changing an amount of delay to be added to a refresh control signal between the first mode and the second mode.

10. The redundancy method according to claim 6, further comprising:
copying, when the first mode is switched to the second mode, data stored in a memory cell in the redundancy area to a memory cell in the normal area, and
copying, when the second mode is switched to the first mode, data stored in a memory cell in the normal area to a memory cell in the redundancy area.
